(19) United States
(12) Patent Application Publication
(10) Pub. No.: US 2025/0157900 A1
(43) Pub. Date: May 15, 2025

(54) SEMICONDUCTOR PACKAGING STRUCTURES AND METHODS FOR FORMING THE SAME

(71) Applicant: YANGTZE MEMORY TECHNOLOGIES CO., LTD., Wuhan (CN)

(72) Inventors: Hao Zheng, Wuhan (CN); Dongyu Fan, Wuhan (CN); Peng Chen, Wuhan (CN); Zhong Lv, Wuhan (CN); Zhiliang Xia, Wuhan (CN); Zongliang Huo, Wuhan (CN)

(21) Appl. No.: 18/515,985

(22) Filed: Nov. 21, 2023

(30) Foreign Application Priority Data
Nov. 14, 2023 (CN) 202311530604.2

(51) Int. Cl. H01L 23/498; H01L 21/48; H01L 23/00; H01L 25/00; H01L 25/18; H10B 80/00

(52) U.S. Cl. CPC H01L 23/49811; H01L 21/4853; H01L 23/49822; H01L 23/49833; H01L 24/16; H01L 25/18; H01L 25/50; H10B 80/00; H01L 2224/16227

(57) ABSTRACT

In certain aspects, a semiconductor packaging structure includes an interposer structure, which includes an interconnect bridge, a device circuit, a set of conductive elements, and a molding layer. The interconnect bridge includes a stack of conductive layers and dielectric layers that are disposed alternately and an interconnect structure formed in the stack and penetrating at least part of the stack to connect to a conductive layer in the stack. The device circuit is disposed on and coupled to the interconnect bridge. The set of conductive elements is disposed on and coupled to the interconnect bridge. The set of conductive elements is disposed on a periphery of the device circuit. The interconnect structure of the interconnect bridge is connected to at least one conductive element from the set of conductive elements. The molding layer encapsulates the device circuit and the set of conductive elements.

### CROSS-REFERENCE TO RELATED APPLICATIONS

This application claims the benefit of priority to Chinese Application No. 202311530604.2, filed on Nov. 14, 2023, which is incorporated herein by reference in its entirety.

### BACKGROUND

The present disclosure relates to semiconductor packaging structures and fabrication methods thereof.

Package-on-Package (POP) is a semiconductor packaging scheme that involves the stacking of two or more packages on top of one another. Signals can be routed between the packages through standard package interfaces. POP provides a packaging solution for applications that require more features in less space like mobile terminals (e.g., smart phones, digital cameras, MP3 players, mobile gaming devices, etc.).

### SUMMARY

In one aspect, a semiconductor packaging structure includes a device package and a first memory package. The device package includes a substrate, a device circuit disposed on and coupled to the substrate, a set of vertical conductive elements disposed on and coupled to the substrate, and a molding layer encapsulating the device circuit and the set of vertical conductive elements. The set of vertical conductive elements is disposed on a periphery of the device circuit. The first memory package is stacked on the molding layer and coupled to the substrate through the set of vertical conductive elements.

In some implementations, the semiconductor packaging structure further includes a second memory package disposed on and coupled to the substrate side by side with the device package.

In some implementations, the device circuit is disposed on a first side of the substrate. The semiconductor packaging structure further includes a printed circuit board (PCB) disposed on a second side opposite to the first side of the substrate and coupled to the substrate on the second side of the substrate.

In some implementations, the semiconductor packaging structure further includes a second memory package disposed on the PCB side by side with the device package and coupled to the PCB.

In some implementations, the device circuit includes a system on chip (SoC), and the device package includes an SoC package. The first memory package includes a volatile memory device. The second memory package includes a non-volatile memory device and a memory controller.

In some implementations, the device circuit includes an SoC, and the device package includes an SoC package. The first memory package is an integrated memory package including a volatile memory device, a non-volatile memory device, and a memory controller.

In some implementations, the set of vertical conductive elements includes one or more conductive elements that are vertically bonded to one or more contacts on the substrate, respectively.

In some implementations, a material of the set of vertical conductive elements includes gold.

In some implementations, a size of a top surface of a vertical conductive element from the set of vertical conductive elements is equal to a size of a bottom surface of the vertical conductive element.

In another aspect, a semiconductor packaging structure includes an interposer structure. The interposer structure includes a first interconnect bridge, a device circuit, a set of conductive elements, and a molding layer. The first interconnect bridge includes a stack of conductive layers and dielectric layers that are disposed alternately and an interconnect structure formed in the stack and penetrating at least part of the stack to connect to a conductive layer in the stack. The device circuit is disposed on the first interconnect bridge and coupled to the first interconnect bridge. The set of conductive elements is disposed on the first interconnect bridge and coupled to the first interconnect bridge. The set of conductive elements is disposed on a periphery of the device circuit, and the interconnect structure of the first interconnect bridge is connected to at least one conductive element from the set of conductive elements. The molding layer encapsulates the device circuit and the set of conductive elements.

In some implementations, the device circuit is coupled to the interconnect structure through a set of solder balls formed on the first interconnect bridge. Or, the device circuit is coupled to the interconnect structure using hybrid bonding.

In some implementations, the set of conductive elements is vertically bonded to a first set of contacts on the first interconnect bridge, respectively.

In some implementations, the device circuit and the set of conductive elements are formed on a first side of the first interconnect bridge. The semiconductor packaging structure further includes a PCB formed on a second side opposite to the first side of the first interconnect bridge and coupled to the first interconnect structure of the first interconnect bridge.

In some implementations, the interposer structure further includes a second interconnect bridge disposed on the molding layer and coupled to the set of conductive elements. The semiconductor packaging structure further includes an integrated memory package stacked on and coupled to the second interconnect bridge of the interposer structure.

In some implementations, the integrated memory package is coupled to the second interconnect bridge using hybrid bonding.

In some implementations, the set of conductive elements is vertically bonded to a second set of contacts on the second interconnect bridge, respectively.

In some implementations, the device circuit includes an SoC. The integrated memory package includes a volatile memory device, a non-volatile memory device stacked on the volatile memory device, and a memory controller.

In still another aspect, an interposer structure includes a first interconnect bridge, a device circuit, a set of conductive elements, a molding layer, and a second interconnect bridge. The device circuit is disposed on the first interconnect bridge and coupled to the first interconnect bridge. The set of conductive elements is disposed on the first interconnect bridge and coupled to the first interconnect bridge. The set of conductive elements is disposed on a periphery of the device circuit. The molding layer encapsulates the device circuit and the set of conductive elements. The second interconnect bridge is disposed on the molding layer and coupled to the set of conductive elements.

In some implementations, the first interconnect bridge includes a first stack of conductive layers and dielectric layers that are disposed alternately and a first interconnect structure formed in the first stack and penetrating at least part of the first stack to connect to a first conductive layer in the first stack. The second interconnect bridge includes a second stack of conductive layers and dielectric layers that are disposed alternately and a second interconnect structure formed in the second stack and penetrating at least part of the second stack to connect to a second conductive layer in the second stack.

In some implementations, at least one conductive element from the set of conductive elements is connected to the first interconnect structure of the first interconnect bridge and the second interconnect structure of the second interconnect bridge.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a semiconductor packaging structure according to some examples.

FIG. 1B illustrates a schematic view of a cross-section of another semiconductor packaging structure according to some examples.

FIG. 2A illustrates a schematic view of a cross-section of a semiconductor packaging structure, according to some aspects of the present disclosure.

FIG. 2B illustrates a schematic view of a cross-section of another semiconductor packaging structure, according to some aspects of the present disclosure.

FIG. 2C illustrates a schematic view of a cross-section of still another semiconductor packaging structure, according to some aspects of the present disclosure.

FIG. 3 illustrates a schematic view of a cross-section of yet another semiconductor packaging structure, according to some aspects of the present disclosure.

FIG. 4A illustrates a schematic top view of an interconnect bridge, according to some aspects of the present disclosure.

FIG. 4B illustrates a schematic view of a first cross-section of the interconnect bridge of FIG. 4A, according to some aspects of the present disclosure.

FIG. 4C illustrates a schematic view of a second cross-section of the interconnect bridge of FIG. 4A, according to some aspects of the present disclosure.

FIG. 5 is a flowchart of a first method for forming a semiconductor packaging structure, according to some aspects of the present disclosure.

FIG. 6 is a flowchart of a second method for forming a semiconductor packaging structure, according to some aspects of the present disclosure.

FIG. 7 is a flowchart of a third method for forming a semiconductor packaging structure, according to some aspects of the present disclosure.

FIG. 8A is a flowchart of a first method for forming a device package, according to some aspects of the present disclosure.

FIGS. 8B-8E illustrate a first fabrication process for forming a device package, according to some aspects of the present disclosure.

FIG. 9A is a flowchart of a second method for forming a device package, according to some aspects of the present disclosure.

FIGS. 9B-9F illustrate a second fabrication process for forming a device package, according to some aspects of the present disclosure.

FIG. 10 is a flowchart of a fourth method for forming a semiconductor packaging structure, according to some aspects of the present disclosure.

FIG. 11A is a flowchart of a method for forming an interposer structure, according to some aspects of the present disclosure.

FIGS. 11B-11F illustrate a fabrication process for forming an interposer structure, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical contacts are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances.

As used herein, the term “vertical/vertically” means nominally perpendicular to the lateral surface of a substrate. As used herein, the x axis and the y axis can each represent a horizontal direction and can be in a horizontal plane. The z axis can represent a vertical direction and can be perpendicular to the horizontal plane. The y axis is perpendicular to the x-z plane.

Due to having a limited motherboard area, a mobile terminal may impose high requirements on its memory devices such as having high performance but with a small area. A heterogeneously integrated memory chip may provide a solution that can well meet the high requirements of the mobile terminal, where the heterogeneously integrated memory chip may be formed by memory devices with different structures. Currently, there are few heterogeneous integration solutions that can form memory chips with satisfying high performance and small area. Furthermore, the cost for forming the heterogeneously integrated memory chips is also high.

To address one or more of the aforementioned issues, the present disclosure introduces a heterogeneous integration solution that can form semiconductor packaging structures with high transmission bandwidth, low transmission delay, and small package area. For example, a semiconductor packaging structure disclosed herein includes a device package, a first memory package, and a second memory package. The device package and the second memory package can be disposed side by side on the same PCB or the same substrate. The first memory package may be stacked on and connected to the device package. The device package may include a substrate, a device circuit disposed on and electrically coupled to the substrate, a set of conductive elements vertically disposed on and electrically bonded to the substrate, and a molding layer encapsulating the device circuit and the set of conductive elements. The usage of the set of conductive elements can avoid etching holes in the molding layer because the set of conductive elements can be directly bonded to the substrate, and a manufacture cost can be reduced thereof.

In another example, a semiconductor packaging structure disclosed herein may include an interposer structure and an integrated memory package stacked on the interposer structure. The interposer structure may include a first interconnect bridge, a device circuit such as an SoC, and a second interconnect bridge. The device circuit can be disposed on and electrically coupled to the first interconnect bridge, so that the first interconnect bridge can function as a fan out of the device circuit. By using the first interconnect bridge, the density of the fan out can be increased. The first and second interconnect bridges can be connected with each other through a set of conductive elements to achieve a vertical connection between the first and second interconnect bridges with an increased interconnection density. The usage of the set of conductive elements can avoid etching holes in a molding layer of the interpose structure, and a manufacture cost can be reduced thereof. The first and second interconnect bridges may have a narrow wiring distance so that the bandwidth of the signal transmission can be increased.

In some implementations, the integrated memory package can be a Universal Flash Storage (UFS) based multichip package (e.g., UFS based multimedia card) or an embedded multichip package (e.g., embedded multimedia card (eMMC)). The integrated memory package may include a non-volatile (NV) memory device (e.g., a NAND Flash memory device) and a volatile memory device (e.g., DRAM). The volatile memory device can be placed closer to the interposer structure than the non-volatile memory device to ensure that the volatile memory device has a high communication speed with the device circuit. Further, the second interconnect bridge of the interposer structure may replace a substrate of the integrated memory package to achieve high-bandwidth signal transmission between the integrated memory package and the device circuit. Additionally, the second interconnect bridge of the interposer structure may be bonded to the integrated memory package using a hybrid bonding to achieve fast signal transmission.

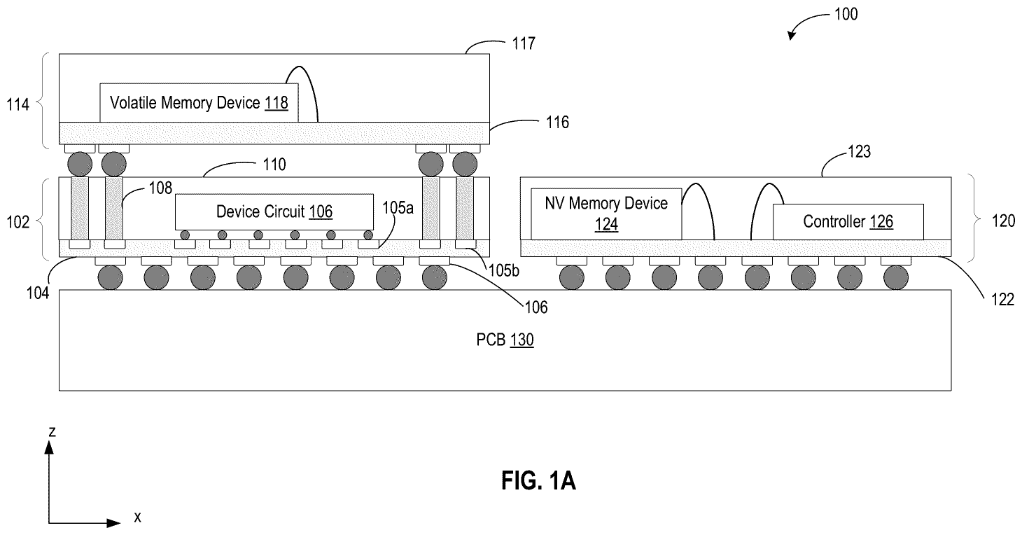

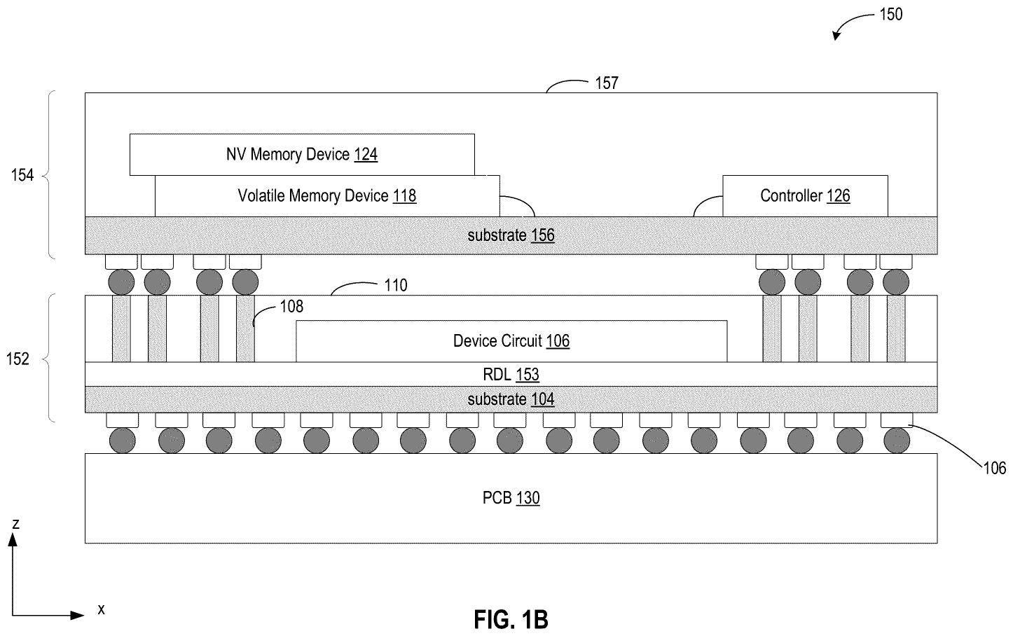

FIG. 1A illustrates a schematic view of a cross-section of a semiconductor packaging structure 100 according to some examples. Semiconductor packaging structure 100 may include a device package 102 and a first memory package 114 stacked on and electrically connected to device package 102. In some implementations, device package 102 may include a substrate 104, a device circuit 106 disposed on substrate 104, a molding layer 110 encapsulating device circuit 106, and a plurality of contact structures 108 extending through molding layer 110 and connected with substrate 104.

In some implementations, substrate 104 may be an organic substrate. Substrate 104 may be a laterally-oriented substrate with two lateral surfaces (e.g., the top surface and the bottom surface) extending laterally in the x-y plane. Substrate 104 may include a plurality of contacts 105 (e.g., 105a, 105b) on the top surface and a plurality of contacts 106 on the bottom surface. In some implementations, substrate 104 includes polysilicon.

Device circuit 106 may be disposed on the top surface of substrate 104 and connected to substrate 104. For example, device circuit 106 may be electrically coupled to a first set of contacts 105a on substrate 104 through a set of solder balls, respectively. In some implementations, device circuit 106 may include an SoC or any other suitable circuit structure. For example, device package 102 may be an SoC package.

Molding layer 110 may be formed on substrate 104 to encapsulate and cover device circuit 106, so as to protect device circuit 106 and reduce physical damage and/or chemical damages (such as oxidation, damage caused by humidity) to device circuit 106. Molder layer 110 may include epoxy resin or any other suitable molding compound.

Contact structures 108 may penetrate molding layer 110 to connect with substrate 104. For example, contact structures 108 may extend through molding layer 110 so that bottom surfaces of contact structures 108 can be electrically connected with a second set of contacts 105b on substrate 104. The second set of contacts 105b may be electrically connected with the first set of contacts 105a, so that contact structures 108 may be electrically connected with device circuit 106. In some implementations, openings can be formed within molding layer 110 (e.g., by etching molding layer 110 to form holes in molding layer 110). Then, the openings can be filled with conductive materials (e.g., metal such as Cu, Tin, etc., or any other suitable conductive materials) to form contact structures 108. In some implementations, contact structures 108 may be formed on a periphery of device circuit 106. In some implementations, solder balls may be formed on the top surfaces of contact structures 108. Each of the solder balls may serve as a signal input/output terminal. Through the solder balls, signals from first memory package 114 can be inputted into device package 102, and signals from device package 102 can be output to first memory package 114.

First memory package 114 may be stacked on molding layer 110, and may be electrically coupled to contact structures 108 of device package 102 (e.g., through solder balls). Then, first memory package 114 may be electrically coupled to substrate 104 (as well as device circuit 106) of device package 102 through contact structures 108. First memory device 114 may include a substrate 116 and a volatile memory device 118 formed on substrate 116. Volatile memory device 118 can be a DRAM, and electrically connected with substrate 116. A molding layer 117 may be formed on substrate 116 to encapsulate and cover volatile memory device 118.

In some implementations, semiconductor packaging structure 100 may further include a printed circuit board (PCB) 130 disposed on a side of substrate 104 opposite to that of device package 102. For example, device package 102 may be disposed on a first side of substrate 104, whereas PCB 130 may be disposed on a second side opposite to the first side of substrate 104. PCB 130 may be coupled to substrate 104. For example, PCB 130 may be electrically coupled to contacts 106 on the second side of substrate 104 through solder balls as illustrated in FIG. 1A. PCB 130 may be connected to an external device (not shown in the figure).

In some implementations, semiconductor packaging structure 100 may further include a second memory package 120 disposed on PCB 130 side by side with device package 102. Second memory package 120 may be coupled to PCB 130. For example, second memory package 120 may be electrically coupled to PCB 130 through solder balls as illustrated in FIG. 1A. Second memory package 120 may include a substrate 122, a non-volatile memory device 124, a memory controller 126, and a molding layer 123 that is disposed on substrate 122 and encapsulates non-volatile memory device 124 and memory controller 126. Non-volatile memory device 124 can be a NAND Flash memory device or any other suitable non-volatile memory device. Memory controller 126 may control the operation of non-volatile memory device 124. Non-volatile memory device 124 and memory controller 126 may be electrically coupled to substrate 122.

FIG. 1B illustrates a schematic view of a cross-section of another semiconductor packaging structure 150 according to some examples. Semiconductor packaging structure 150 may include components like those of semiconductor packaging structure 100 of FIG. 1A, and the similar description will not be repeated herein.

In some implementations, semiconductor packaging structure 150 may include a device package 152 and an integrated memory package 154 stacked on device package 152. In some implementations, semiconductor packaging structure 150 may further include PCB 130 disposed on a first side of device package 152, whereas integrated memory package 154 is disposed on a second side opposite to the first side of device package 152.

In some implementations, device package 152 may include substrate 104, a redistribution layer (RDL) 153 disposed on substrate 104, device circuit 106 disposed on RDL 153 and connected to RDL 153, molding layer 110 disposed on RDL 153 and encapsulating device circuit 106, and contact structures 108 extending through molding layer 110 and connected with RDL 153. Compared with device package 102 of FIG. 1A, device package 152 of FIG. 1B additionally includes RDL 153 between device circuit 106 and substrate 104.

RDL 153 may include at least one conductive layer and at least one dielectric layer. The at least one conductive layer may be coupled to one or more of substrate 104, device circuit 106, and contact structures 108 to achieve electrical connection among substrate 104, device circuit 106, and contact structures 108. The at least one conductive layer can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The at least one dielectric layer can include dielectric materials including, but not limited to, silicon oxide, silicon nitride, silicon oxynitride, or any combination thereof.

Contact structures 108 may penetrate molding layer 110 to connect with RDL 153. In some implementations, openings can be formed in molding layer 110 through etching. The openings can be filled with conductive materials to form contact structures 108 within molding layer 110.

Integrated memory package 154 may be stacked on molding layer 110, and may be electrically coupled to contact structures 108 of device package 152 (e.g., through solder balls). Then, integrated memory package 154 may be electrically coupled to substrate 104 (as well as device circuit 106) of device package 152 through contact structures 108 and RDL 153. Integrated memory device 154 may be an integration of first memory device 114 and second memory device 120 of FIG. 1A. For example, integrated memory device 154 may include a substrate 156, volatile memory device 118 disposed on substrate 156, non-volatile memory device 124 disposed on volatile memory device 118, and memory controller 126 disposed on substrate 156. Volatile memory device 118, non-volatile memory device 124, and memory controller 126 may be electrically coupled to substrate 156. For example, volatile memory device 118 may have a shorter distance to substrate 156 than that of non-volatile memory device 124, such that volatile memory device 118 may have a shorter distance to device circuit 106 than that of non-volatile memory device 124 to ensure a high communication speed between volatile memory device 118 and device circuit 106. A molding layer 157 may be formed on substrate 156 to encapsulate and cover volatile memory device 118, non-volatile memory device 124, and memory controller 126. In some implementations, integrated memory package 154 can be a UFS-based multichip package or an eMMC.

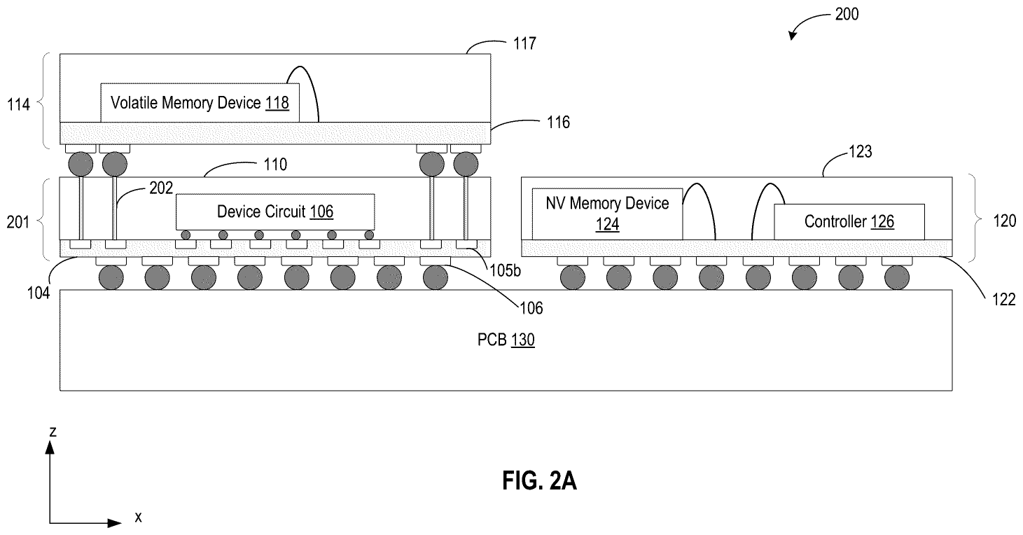

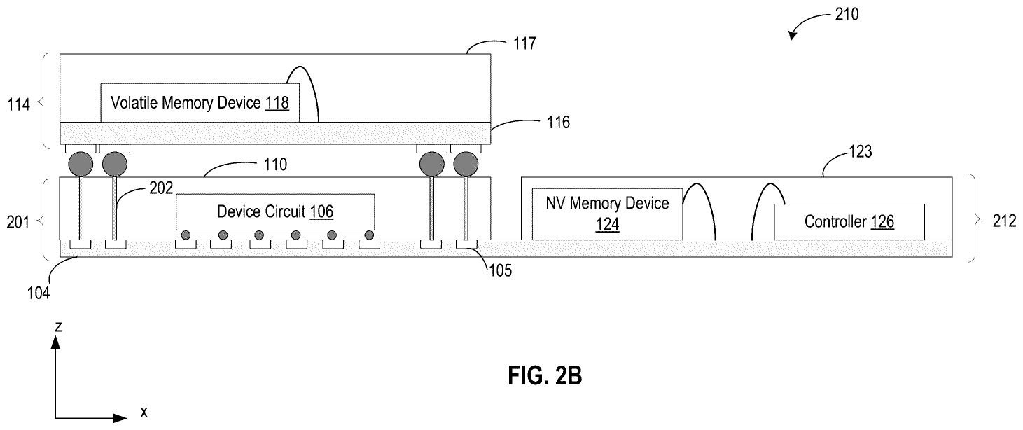

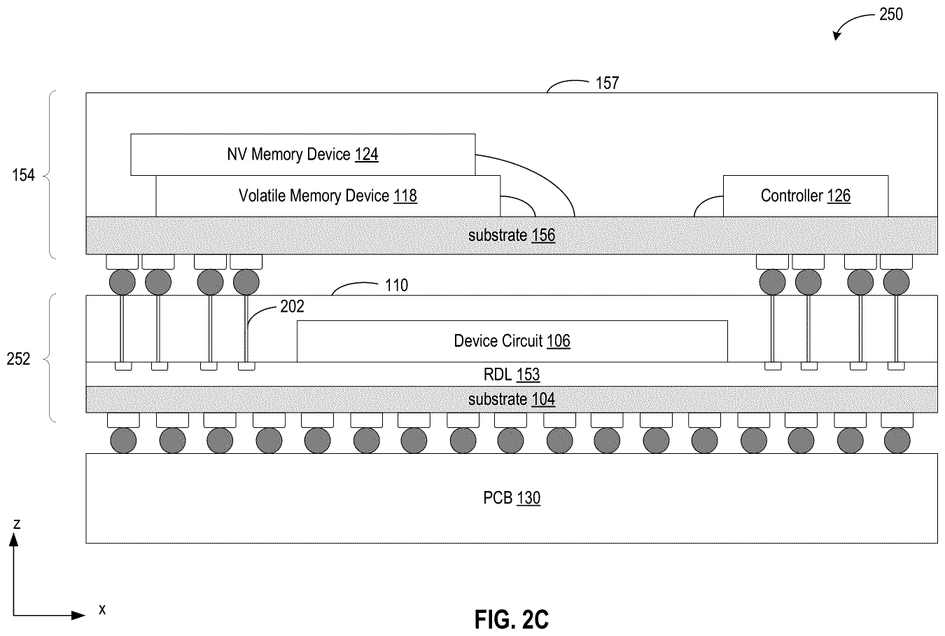

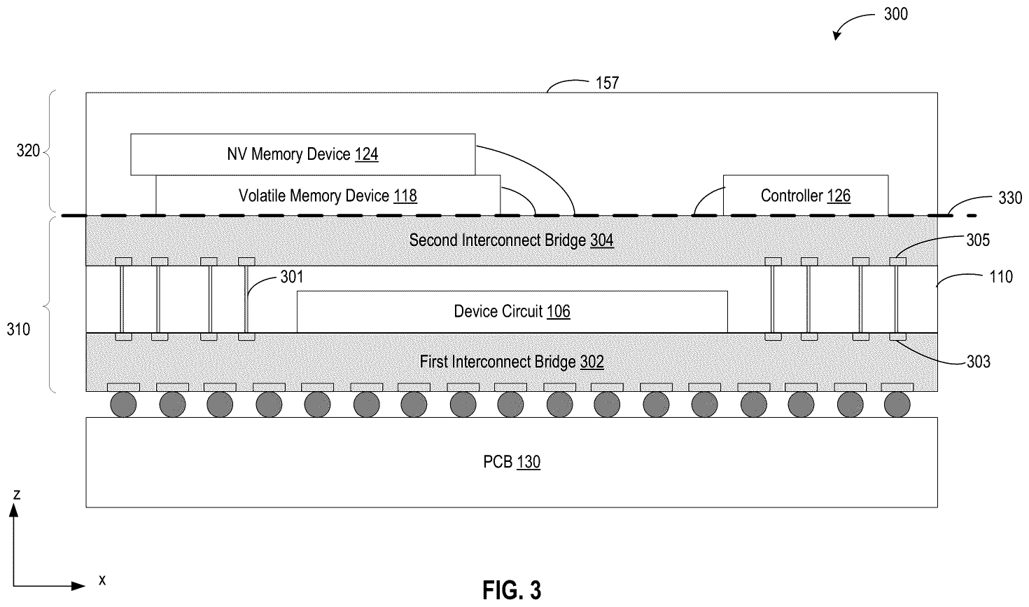

As shown in FIGS. 1A and 1B, contact structures 108 may be formed in molding layer 110 by firstly etching molding layer 110 to form holes and then filling the holes with conductive materials. The manufacture cost for forming contact structures 108 is high while a density of interconnection achieved with contact structures 108 is low. Consistent with some aspects of the present disclosure, a set of vertical conductive elements 202 as shown below in FIGS. 2A-2C and 3 can be used to replace contact structures 108 to achieve a higher density of interconnection. As described below in more detail, the formation of vertical conductive elements 202 is different from the formation of contact structures 108. For example, in FIGS. 2A-2B, a set of vertical conductive elements 202 can be formed by vertically disposing and electrically bonding one or more conductive structures (e.g., conductive wires, conductive pillars, conductive cylinders, etc.) to one or more contacts on substrate 104. In FIG. 2C, a set of vertical conductive elements 202 can be formed by vertically disposing and electrically bonding one or more conductive structures to one or more contacts on RDL 153. In FIG. 3, a set of vertical conductive elements 202 can be formed by vertically disposing and electrically bonding one or more conductive structures to one or more contacts on a first interconnect bridge 302. The set of vertical conductive elements 202 can also be electrically bonded to one or more contacts on a second interconnect bridge 304. That is, in the formation of vertical conductive elements 202, there is no need to perform etching on molding layer 110 so as to form holes within molding layer 110, so that the manufacture cost can be reduced.

FIG. 2A illustrates a schematic view of a cross-section of a semiconductor packaging structure 200, according to some aspects of the present disclosure. Semiconductor packaging structure 200 may include components like those of semiconductor packaging structure 100 of FIG. 1A, and the similar description will not be repeated herein.

In some implementations, semiconductor packaging structure 200 may include a device package 201 and first memory package 114 stacked on and electrically connected to device package 201. In some implementations, semiconductor packaging structure 200 may further include PCB 130 disposed on a side of device package 201 opposite to that first memory package 114. In some implementations, semiconductor packaging structure 200 may further include second memory package 120 disposed on PCB 130 side by side with device package 201.

In some implementations, device package 201 may include substrate 104, device circuit 106 disposed on substrate 104, molding layer 110 encapsulating device circuit 106, and a set of vertical conductive elements 202 extending through molding layer 110 and connected with substrate 104. Comparing FIG. 1A with FIG. 2A, contact structures 108 of FIG. 1A are replaced by the set of vertical conductive elements 202 in FIG. 2A.

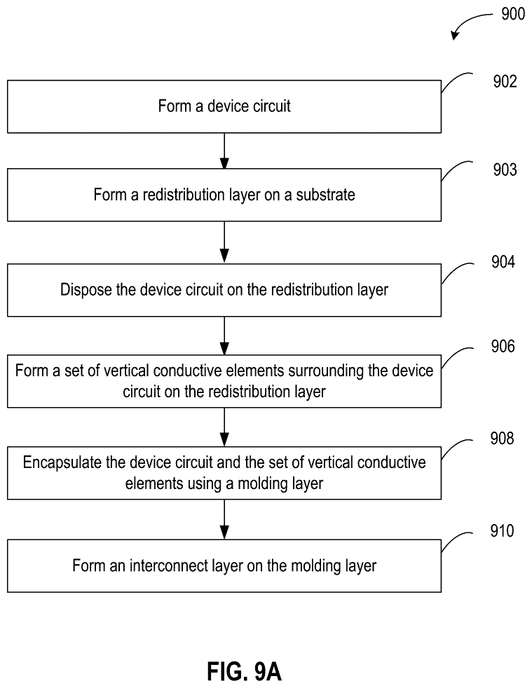

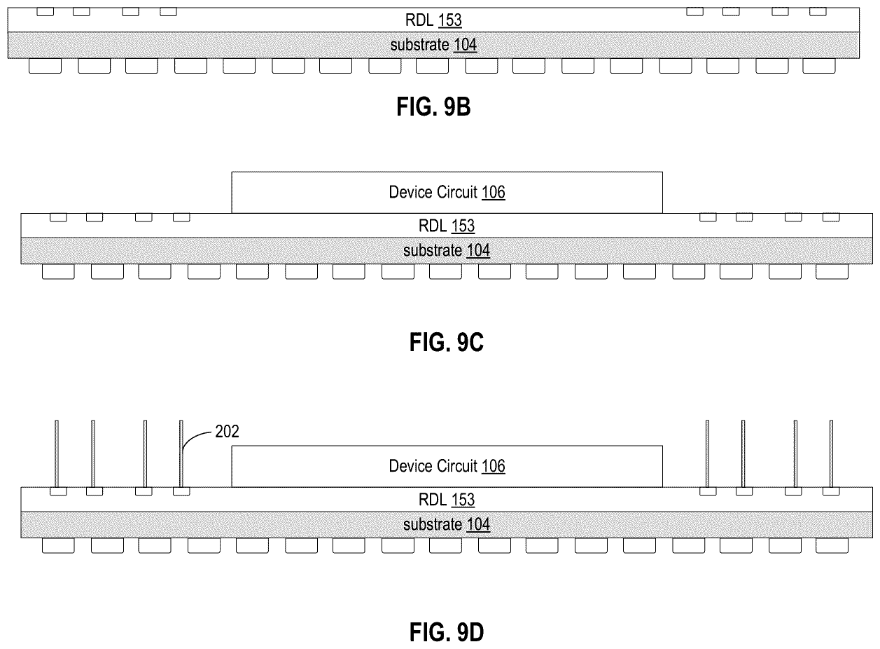

The set of vertical conductive elements 202 may penetrate molding layer 110 and may be connected with substrate 104. For example, the set of vertical conductive elements 202 may include one or more conductive elements that are vertically bonded to the set of contacts 105b (e.g., contact pads) on substrate 104, respectively. In some implementations, the set of vertical conductive elements 202 may be formed on a periphery of device circuit 106. In some implementations, solder balls may be formed on the top surfaces of vertical conductive elements 202. In some implementations, the material of the set of vertical conductive elements 202 may include gold or any other suitable conductive materials. A size of the top surface of each vertical conductive element 202 may be equal to a size of the bottom surface of the vertical conductive element 202. The formation of the set of vertical conductive elements 202 is described below in more detail with reference to FIGS. 8B-8E.

FIG. 2B illustrates a schematic view of a cross-section of another semiconductor packaging structure 210, according to some aspects of the present disclosure. Semiconductor packaging structure 210 may have components like those of semiconductor packaging structure 100 of FIG. 1A or semiconductor packaging structure 200 of FIG. 2A, and the similar description will not be repeated herein. Compared with semiconductor packaging structure 200 of FIG. 2A, semiconductor packaging structure 210 of FIG. 2B may not include PCB 130. In FIG. 2B, device package 201 and second memory package 212 may be formed on the same substrate 104. Second memory package 212 may be electrically coupled to device package 201 through substrate 104.

FIG. 2C illustrates a schematic view of a cross-section of still another semiconductor packaging structure 250, according to some aspects of the present disclosure. Semiconductor packaging structure 250 may include components like those of semiconductor packaging structure 150 of FIG. 1B or semiconductor packaging structure 200 of FIG. 1A, and the similar description will not be repeated herein.

In some implementations, semiconductor packaging structure 250 may include a device package 252 and integrated memory package 154 stacked on and electrically connected to device package 252. Semiconductor packaging structure 250 may further include PCB 130 disposed on a side of device package 252 opposite to that of integrated memory package 154.

In some implementations, device package 252 may include substrate 104, RDL 153 disposed on substrate 104, device circuit 106 disposed on RDL 153, molding layer 110 disposed on RDL 153, and a set of vertical conductive elements 202 extending through molding layer 110 and connected with RDL 153. Compared with device package 152 of FIG. 1B, contact structures 108 of FIG. 1B are replaced by the set of vertical conductive elements 202.

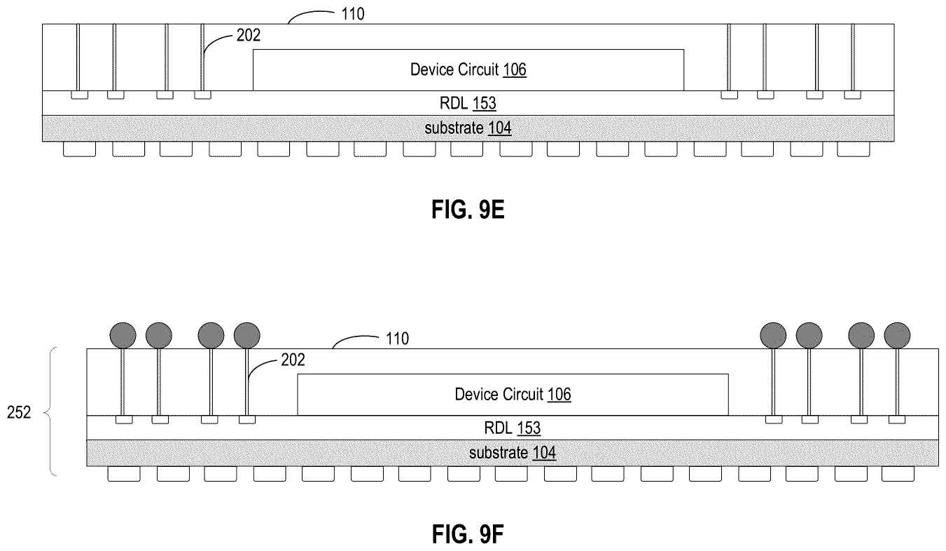

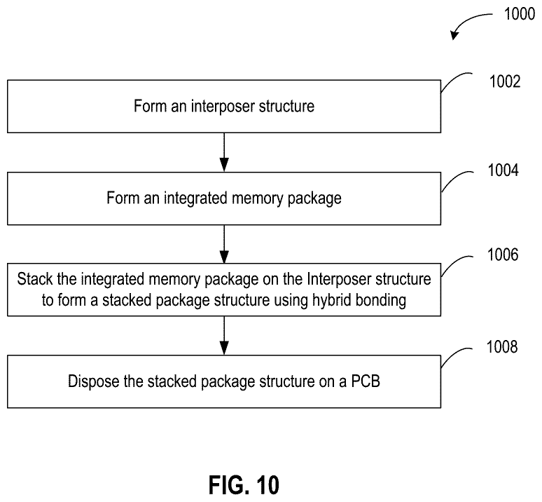

The set of vertical conductive elements 202 may penetrate molding layer 110 and may be connected with a set of contacts on RDL 153. For example, the set of vertical conductive elements 202 may include one or more conductive elements that are vertically bonded to one or more contacts on a periphery of RDL 153. The set of vertical conductive elements 202 may be electrically connected with device circuit 106 through RDL 153. The formation of the set of vertical conductive elements 202 in semiconductor packaging structure 250 is described below in more detail with reference to FIGS. 9B-9F.

FIG. 3 illustrates a schematic view of a cross-section of yet another semiconductor packaging structure 300, according to some aspects of the present disclosure. Semiconductor packaging structure 300 may include components like those of semiconductor packaging structure 150 of FIG. 1B or semiconductor packaging structure 250 of FIG. 2C, and the similar description will not be repeated herein.

In some implementations, semiconductor packaging structure 300 may include an interposer structure 310 and an integrated memory package 320 stacked on and electrically connected to interposer structure 310. Semiconductor packaging structure 300 may further include PCB 130 disposed on a side of interposer structure 310 opposite to that of integrated memory package 320.

In some implementations, interposer structure 310 may include first interconnect bridge 302, device circuit 106 disposed on and coupled to first interconnect bridge 302, a set of conductive elements 301 disposed on first interconnect bridge 302 and coupled to first interconnect bridge 302, molding layer 110 encapsulating device circuit 106 and the set of conductive elements 301, and a second interconnect bridge 304 disposed on molding layer 110. The set of conductive elements 301 can include, for example, the set of vertical conductive elements 202 shown in FIGS. 2A-2C. The set of conductive elements 301 can be disposed on a periphery of device circuit 106. Compared with device package 252 of FIG. 2C, interposer structure 310 of FIG. 3 replaces substrate 104 and RDL 153 of device package 252 with first interconnect bridge 302.

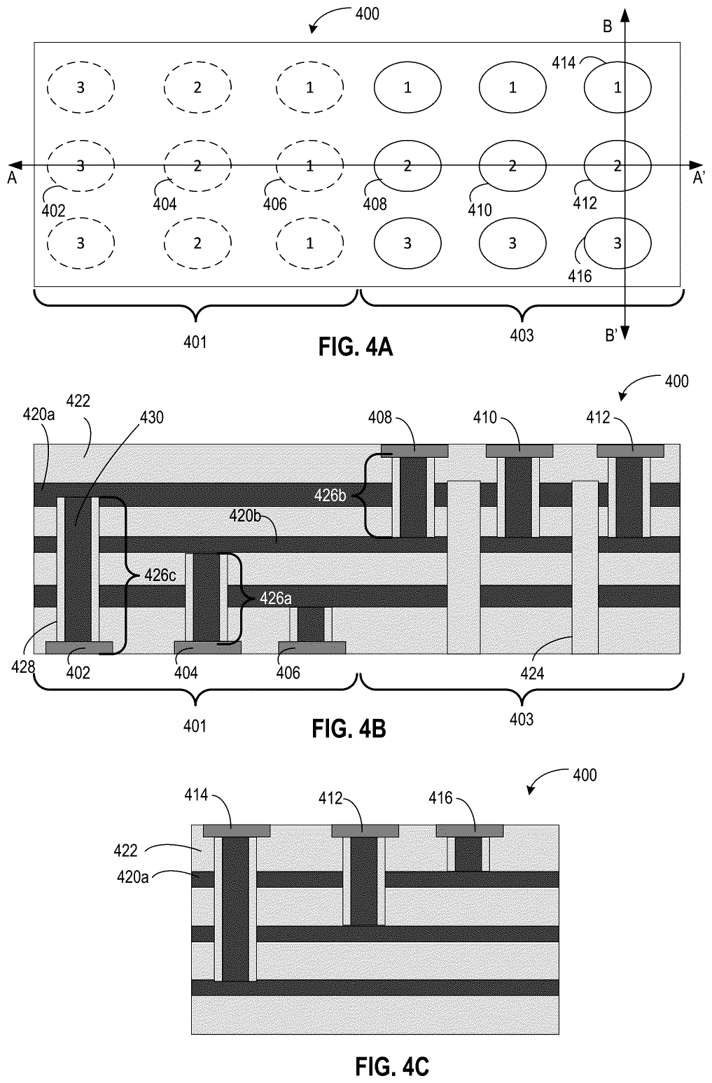

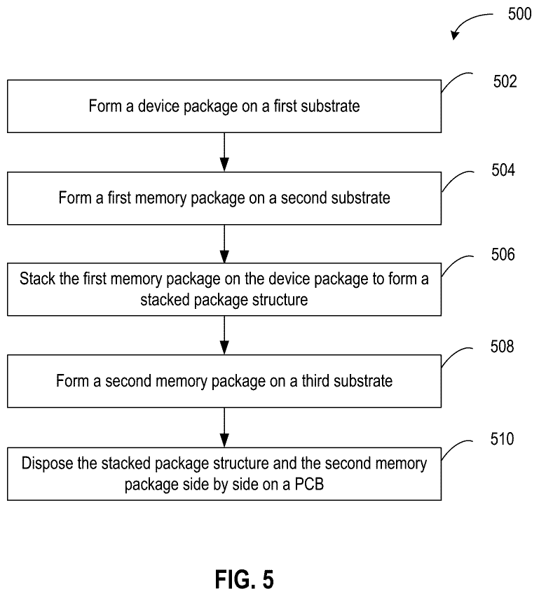

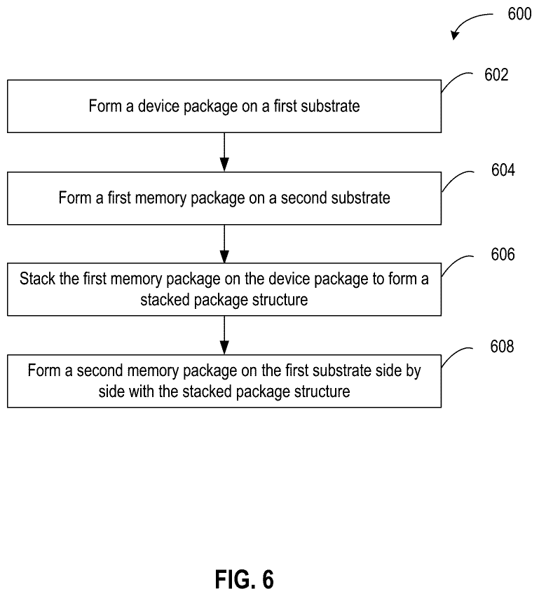

First interconnect bridge 302 may include a first stack of conductive layers and dielectric layers that are disposed alternately. First interconnect bridge 302 may further include at least one first interconnect structure formed in the first stack and penetrating at least part of the first stack to connect to a first conductive layer in the first stack. Similarly, second interconnect bridge 304 may include a second stack of conductive layers and dielectric layers that are disposed alternately. Second interconnect bridge 304 may further include at least one second interconnect structure formed in the second stack and penetrating at least part of the second stack to connect to a second conductive layer in the second stack. An example of first or second interconnect bridge 302 or 304 is illustrated below with references to FIGS. 4A-4C.

In some implementations, the set of conductive elements 301 can be vertically bonded to a first set of contacts 303 on first interconnect bridge 302, respectively. The set of conductive elements 301 can also be vertically bonded to a second set of contacts 305 on second interconnect bridge 304, respectively. For example, a bottom surface of a conductive element 301 can be bonded to a contact 303 of a first interconnect structure in first interconnect bridge 302. A top surface of the conductive element 301 can be bonded to a contact 305 of a second interconnect structure in second interconnect bridge 304. First and second interconnect bridges 302 and 304 can be coupled with each other through the set of conductive elements 301.

In some implementations, device circuit 106 may be coupled to at least one first interconnect structure of first interconnect bridge 302 through a set of solder balls formed on first interconnect bridge 302. Alternatively, device circuit 106 may be coupled to at least one first interconnect structure of first interconnect bridge 302 using hybrid bonding. Hybrid bonding is described below in more detail. Device circuit 106 and the set of conductive elements 301 can be formed on a first side of first interconnect bridge 302, and PCB 130 can be formed on a second side opposite to the first side of first interconnect bridge 302. PCB 130 may be coupled to one or more first interconnect structures of first interconnect bridge 302 through solder balls.

Unlike integrated memory device 154 of FIG. 2C that includes substrate 156, integrated memory device 320 of FIG. 3 may not include a substrate. For example, after forming integrated memory device 154, substrate 156 can be removed from integrated memory device 154 to form integrated memory device 320 of FIG. 3. Integrated memory package 320 may include volatile memory device 118, non-volatile memory device 124 stacked on volatile memory device 118, and memory controller 126, each of which is connected to second interconnect bridge 304.

Unlike FIG. 2C that uses solder balls to connect device package 252 with integrated memory device 154, second interconnect bridge 304 in FIG. 3 can be used to connect interposer structure 310 with integrated memory device 320. In some implementations, integrated memory package 320 may be coupled to second interconnect bridge 304 using hybrid bonding. As a result, a hybrid bonding interface 330 can be formed between integrated memory device 320 and interposer structure 310.

In some implementations, hybrid bonding (also known as “metal/dielectric hybrid bonding”) can be a direct bonding technology (e.g., forming bonding between surfaces without using intermediate layers, such as solder or adhesives) and can obtain metal-metal bonding and dielectric-dielectric bonding simultaneously. Hybrid bonding in a face-to-face manner can achieve millions of parallel short interconnects between the bonded semiconductor structures to increase the throughput and input/output (I/O) speed of the semiconductor packaging structure.

Specifically, integrated memory package 320 can be bonded on top of interposer structure 310 in a face-to-face manner at bonding interface 330. For example, second interconnect bridge 304 may include a first bonding layer on its top surface. Integrated memory package 320 can also include a second bonding layer at bonding interface 330. Each of the first and second bonding layers can include a plurality of bonding contacts and dielectrics electrically isolating the bonding contacts. The bonding contacts can include conductive materials, such as Cu. The remaining area of each of the first and second bonding layers can be formed with dielectric materials, such as silicon oxide. The bonding contacts and surrounding dielectrics in each of the first and second bonding layers can be used for hybrid bonding. In some implementations, bonding interface 330 is the place at which the first and second bonding layers are met and bonded. In practice, bonding interface 330 can be a layer with a certain thickness that includes the top surface of the first bonding layer of second interconnect bridge 304 and the bottom surface of the second bonding layer of integrated memory package 320.

Comparing FIG. 2C with FIG. 3, substrate 104 and RDL 153 of FIG. 2C are replaced by first interconnect bridge 302 of FIG. 3. Substrate 156 and the interconnect layer (e.g., solder balls) between integrated memory package 154 and device package 252 of FIG. 2C are replaced by second interconnect bridge 304 of FIG. 3. As a result, a high transmission bandwidth can be achieved in semiconductor packaging structure 300 of FIG. 3. In FIG. 3, the usage of vertical conductive elements 202 can avoid etching holes in molding layer 110 of interpose structure 310, and a manufacture cost can be reduced thereof. The combined application of (a) first and second interconnect bridges 302, 304, (b) the set of vertical conductive elements 202, and (c) hybrid bonding between interposer structure 310 and integrated memory package 320 can achieve signal transmission with ultrahigh density and ultrahigh bandwidth, so that complicated chip stack and signal routing can be implemented. By stacking integrated memory device 320 on interposer structure 310, a package area of semiconductor packaging structure 300 can be saved when compared with semiconductor packaging structure 200 of FIG. 2A or 210 of FIG. 2B.

FIG. 4A illustrates a schematic top view of an interconnect bridge 400, according to some aspects of the present disclosure. FIG. 4B illustrates a schematic view of a first cross-section of interconnect bridge 400 of FIG. 4A at a line A-A′, according to some aspects of the present disclosure. FIG. 4C illustrates a schematic view of a second cross-section of interconnect bridge 400 of FIG. 4A at a line B-B′, according to some aspects of the present disclosure. FIGS. 4A-4C are described below together.

With reference to FIG. 4B, interconnect bridge 400 may include a stack of conductive layers 420 (e.g., 420a, 420b, etc.) and dielectric layers 422 that are disposed alternately. Conductive layers 420 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. Dielectric layers 422 can include dielectric materials including, but not limited to, silicon oxide, silicon nitride, silicon oxynitride, or any combination thereof.

Interconnect bridge 400 may also include a plurality of interconnect structures 426 (e.g., 426a, 426b, 426c, etc.) formed in the stack. The plurality of interconnect structures 426 may extend in the stack with different depths or identical depths, which is not limited herein. Each interconnect structure 426 may penetrate at least part of the stack to connect to a conductive layer 420 in the stack. For example, interconnect structure 426c in FIG. 4B may include a spacer 428, a conductive filler 430, and a contact 402 coupled to conductive filler 430. A first end of conductive filler 430 can be coupled to conductive layer 420a in the stack, and a second end of conductive filler 430 can be coupled to contact 402.

In some implementations, each interconnect structure 426 may be categorized into either a top interconnect structure or a bottom interconnect structure. A top interconnect structure can be an interconnect structure whose contact is formed on the top surface of interconnect bridge 400. A bottom interconnect structure can be an interconnect structure whose contact is formed on the bottom surface of interconnect bridge 400. In some implementations, top interconnect structures and bottom interconnect structures can be formed in different regions of interconnect bridge 400. For example, interconnect bridge 400 can be divided into two regions 401 and 403. Top interconnect structures 426 of interconnect bridge 400 can be formed in region 403, whereas bottom interconnect structures 426 of interconnect bridge 400 can be formed in region 401. As shown in FIG. 4A, contacts (e.g., 408, 410, 412, 414, 416) of top interconnect structures 426 are on the top surface of interconnect bridge 400 and visible in the top view of interconnect bridge 400 (illustrated with solid ellipses in region 403). Contacts (e.g., 402, 404, 406, 408) of bottom interconnect structures 426 are on the bottom surface of interconnect bridge 400 and not visible in the top view of interconnect bridge 400 (illustrated with dashed ellipses in region 401).

Contacts in FIG. 4A are labeled with numbers 1, 2, and 3. If a first contact on the top surface of interconnect bridge 400 is labeled with the same number as a second contact on the bottom surface of interconnect bridge 400, it indicates that they are interconnected with each other. For example, a contact 408 of a top interconnect structure 426b and a contact 404 of a bottom interconnect structure 426a are labeled with the same number “2.” Top interconnect structure 426b and bottom interconnect structure 426a can be connected to the same conductive layer 420b. Then, contact 408 on the top surface can be interconnected with contact 404 on the bottom surface through top interconnect structure 426b, conductive layer 420b, and bottom interconnect structure 426a.

Interconnect bridge 400 may also include a plurality of isolation trenches 424. The plurality of isolation trenches 424 may extend in the stack with different depths or identical depths, which is not limited herein. Each isolation trench 424 may include dielectric materials including, but not limited to, silicon oxide, silicon nitride, silicon oxynitride, or any combination thereof. In some implementations, isolation trench 424 may have the same dielectric materials as dielectric layers 422. In some other implementations, isolation trench 424 may have dielectric materials different from that of dielectric layers 422.

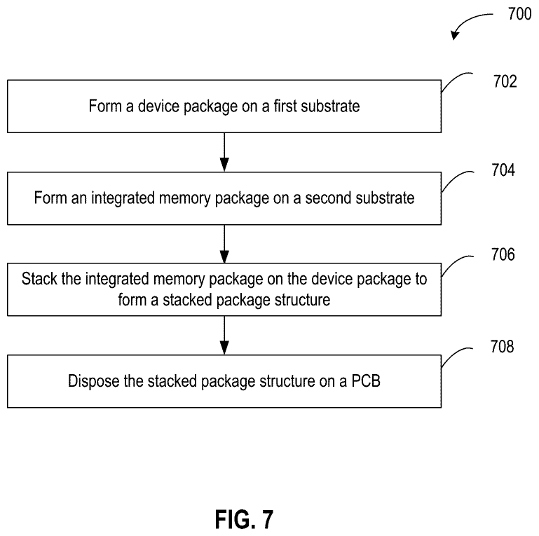

FIG. 5 is a flowchart of a first method 500 for forming a semiconductor packaging structure, according to some aspects of the present disclosure. An example of the semiconductor packaging structure formed by method 500 can be semiconductor packaging structure 200 of FIG. 2A. It is understood that the operations shown in method 500 are not exhaustive and that other operations can be performed as well before, after, or between any of the illustrated operations. Further, some of the operations may be performed simultaneously, or in a different order than shown in FIG. 5.

Referring to FIG. 5, method 500 starts at operation 502, in which a device package can be formed on a first substrate. For example, with reference to FIG. 2A, device package 201 can be formed on substrate 104. An example method of forming the device package at operation 502 is illustrated below with reference to FIGS. 8A-8E.

Method 500 proceeds to operation 504, as illustrated in FIG. 5, in which a first memory package can be formed on a second substrate. For example, with reference to FIG. 2A, first memory package 114 may be formed on substrate 116.

Method 500 proceeds to operation 506, as illustrated in FIG. 5, in which the first memory package can be stacked on the device package to form a stacked package structure. For example, with reference to FIG. 2A, first memory package 114 can be stacked on and coupled to device package 201 to form a stacked package structure.

Method 500 proceeds to operation 508, as illustrated in FIG. 5, in which a second memory package can be formed on a third substrate. For example, with reference to FIG. 2A, second memory package 120 may be formed on substrate 122.

Method 500 proceeds to operation 510, as illustrated in FIG. 5, in which the stacked package structure and the second memory package can be disposed side by side on a PCB. For example, with reference to FIG. 2A, second memory device 120 and the stacked package structure formed by device package 201 and first memory device 114 can be disposed on PCB 130 side by side.

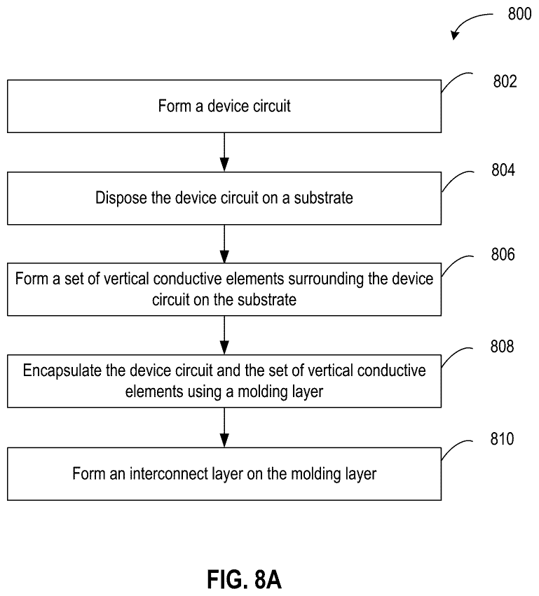

FIG. 6 is a flowchart of a second method 600 for forming a semiconductor packaging structure, according to some aspects of the present disclosure. An example of the semiconductor packaging structure formed by method 600 can be semiconductor packaging structure 210 of FIG. 2B. It is understood that the operations shown in method 600 are not exhaustive and that other operations can be performed as well before, after, or between any of the illustrated operations. Further, some of the operations may be performed simultaneously, or in a different order than shown in FIG. 6.

Referring to FIG. 6, method 600 starts at operation 602, in which a device package can be formed on a first substrate. For example, with reference to FIG. 2B, device package 201 can be formed on substrate 104. An example method of forming the device package at operation 602 is illustrated below with reference to FIGS. 8A-8E.

Method 600 proceeds to operation 604, as illustrated in FIG. 6, in which a first memory package can be formed on a second substrate. For example, with reference to FIG. 2B, first memory package 114 may be formed on substrate 116.

Method 600 proceeds to operation 606, as illustrated in FIG. 6, in which the first memory package can be stacked on the device package to form a stacked package structure. For example, with reference to FIG. 2B, first memory package 114 can be stacked on and coupled to device package 201 to form a stacked package structure.

Method 600 proceeds to operation 608, as illustrated in FIG. 6, in which a second memory package can be formed on the first substrate side by side with the stacked package structure. For example, with reference to FIG. 2B, second memory package 120 may be formed on substrate 104 side by side with the stacked package structure formed by device package 201 and first memory device 114.

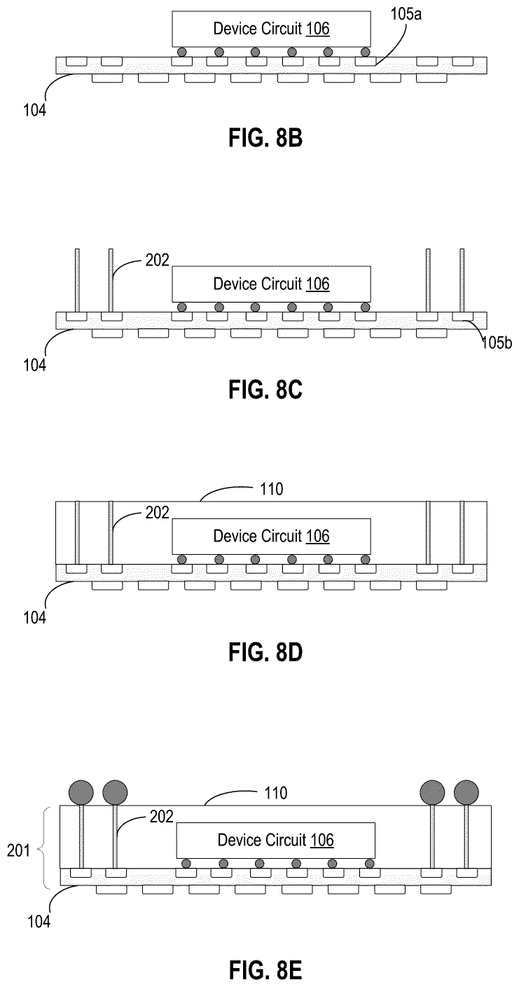

FIG. 7 is a flowchart of a third method 700 for forming a semiconductor packaging structure, according to some aspects of the present disclosure. An example of the semiconductor packaging structure formed by method 700 can be semiconductor packaging structure 250 of FIG. 2C. It is understood that the operations shown in method 700 are not exhaustive and that other operations can be performed as well before, after, or between any of the illustrated operations. Further, some of the operations may be performed simultaneously, or in a different order than shown in FIG. 7.

Referring to FIG. 7, method 700 starts at operation 702, in which a device package can be formed on a first substrate. For example, with reference to FIG. 2C, device package 252 can be formed on substrate 104. An example method of forming the device package at operation 702 is illustrated below with reference to FIGS. 9A-9F.

Method 700 proceeds to operation 704, as illustrated in FIG. 7, in which an integrated memory package can be formed on a second substrate. For example, with reference to FIG. 2C, integrated memory package 154 may be formed on substrate 156.

Method 700 proceeds to operation 706, as illustrated in FIG. 7, in which the integrated memory package can be stacked on the device package to form a stacked package structure. For example, with reference to FIG. 2C, integrated memory package 154 can be stacked on and coupled to device package 252 to form a stacked package structure.

Method 700 proceeds to operation 708, as illustrated in FIG. 7, in which the stacked package structure can be disposed on a PCB. For example, with reference to FIG. 2C, the stacked package structure formed by device package 252 and integrated memory device 154 can be disposed on PCB 130.

FIG. 8A is a flowchart of a first method 800 for forming a device package, according to some aspects of the present disclosure. FIGS. 8B-8E illustrate a first fabrication process for forming a device package, according to some aspects of the present disclosure. An example of the device package described in FIGS. 8A-8E can be device package 201 of FIGS. 2A-2B. FIGS. 8A-8E will be described together. It is understood that the operations shown in method 800 are not exhaustive and that other operations can be performed as well before, after, or between any of the illustrated operations. Further, some of the operations may be performed simultaneously, or in a different order than shown in FIG. 8A.

Referring to FIG. 8A, method 800 starts at operation 802, in which a device circuit can be formed. Method 800 may proceed to operation 804, as illustrated in FIG. 8A, in which the device circuit can be disposed on a substrate. For example, with reference to FIG. 8B, device circuit 106 such as an SoC can be formed. Then, device circuit 106 can be disposed on substrate 104. Device circuit 106 may be connected to a first set of contacts 105a on substrate 104.

Method 800 may proceed to operation 806, as illustrated in FIG. 8A, in which a set of vertical conductive elements surrounding the device circuit can be formed on the substrate. For example, with reference to FIG. 8C, a set of conductive structures (e.g., conductive wires, conductive pillars, conductive cylinders, etc.) can be disposed vertically on substrate 104 and bonded to a second set of contacts 105b on substrate 104 to form a set of vertical conductive elements 202, respectively.

Method 800 may proceed to operation 808, as illustrated in FIG. 8A, in which the device circuit and the set of vertical conductive elements can be encapsulated using a molding layer. For example, as illustrated in FIG. 8D, molding layer 110 can be formed to encapsulate device circuit 106 and the set of vertical conductive elements 202.

Method 800 may proceed to operation 810, as illustrated in FIG. 8A, in which an interconnect layer can be formed on the molding layer. For example, as illustrated in FIG. 8E, a set of solder balls can be formed above molding layer 110. The set of solder balls can be connected with the set of vertical conductive elements 202, respectively.

FIG. 9A is a flowchart of a second method 900 for forming a device package, according to some aspects of the present disclosure. FIGS. 9B-9F illustrate a second fabrication process for forming a device package, according to some aspects of the present disclosure. An example of the device package described in FIGS. 9A-9F can be device package 252 of FIG. 2C. FIGS. 9A-9F will be described together. It is understood that the operations shown in method 900 are not exhaustive and that other operations can be performed as well before, after, or between any of the illustrated operations. Further, some of the operations may be performed simultaneously, or in a different order than shown in FIG. 9A.

Referring to FIG. 9A, method 900 starts at operation 902, in which a device circuit can be formed. Method 900 may proceed to operation 903, as illustrated in FIG. 9A, in which a redistribution layer may be formed on a substrate. Method 900 may proceed to operation 904, as illustrated in FIG. 9A, in which the device circuit can be disposed on the redistribution layer.

For example, device circuit 106 such as an SoC can be formed. With reference to FIG. 9B, RDL 153 may be formed on substrate 104. With reference to FIG. 9C, device circuit 106 can be disposed on RDL 153. Device circuit 106 may be electrically connected to RDL 153.

Method 900 may proceed to operation 906, as illustrated in FIG. 9A, in which a set of vertical conductive elements surrounding the device circuit can be formed on the redistribution layer. For example, with reference to FIG. 9D, a set of conductive structures can be disposed vertically on RDL 153 and bonded to a set of contacts on RDL 153 to form a set of vertical conductive elements 202, respectively.

Method 900 may proceed to operation 908, as illustrated in FIG. 9A, in which the device circuit and the set of vertical conductive elements can be encapsulated using a molding layer. For example, as illustrated in FIG. 9E, molding layer 110 can be formed to encapsulate device circuit 106 and the set of vertical conductive elements 202.

Method 900 may proceed to operation 910, as illustrated in FIG. 9A, in which an interconnect layer can be formed on the molding layer. For example, as illustrated in FIG. 9F, a set of solder balls can be formed above molding layer 110. The set of solder balls can be connected with the set of vertical conductive elements 202, respectively.

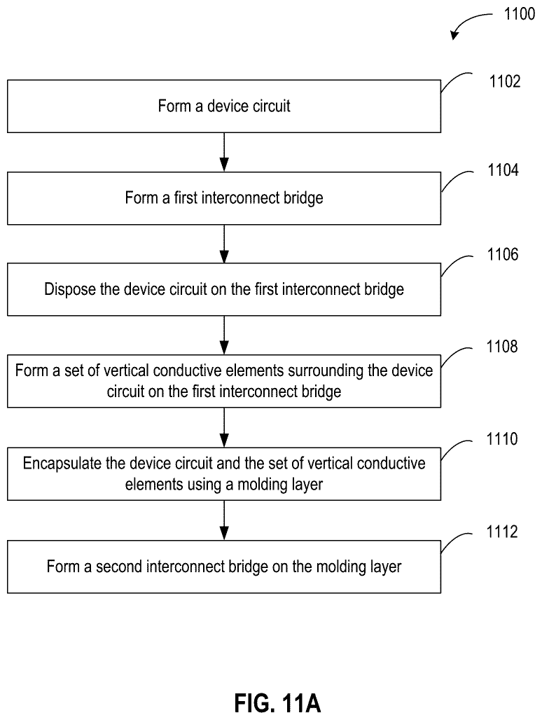

FIG. 10 is a flowchart of a fourth method 1000 for forming a semiconductor packaging structure, according to some aspects of the present disclosure. An example of the semiconductor packaging structure formed by method 1000 can be semiconductor packaging structure 300 of FIG. 3. It is understood that the operations shown in method 1000 are not exhaustive and that other operations can be performed as well before, after, or between any of the illustrated operations. Further, some of the operations may be performed simultaneously, or in a different order than shown in FIG. 10.

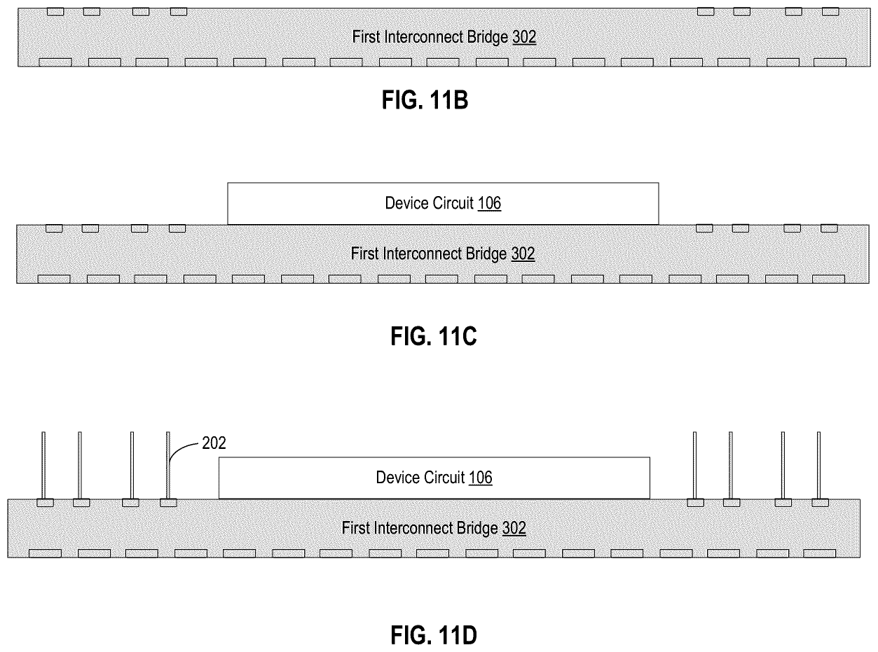

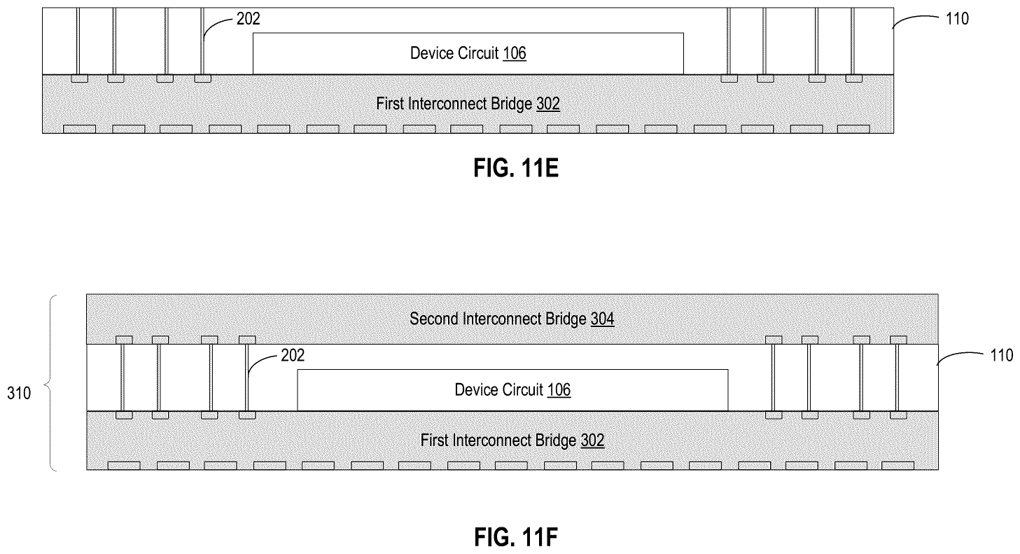

Referring to FIG. 10, method 1000 starts at operation 1002, in which an interposer structure can be formed. For example, with reference to FIG. 3, interposer structure 310 can be formed. An example method of forming interposer structure 310 is illustrated below with reference to FIGS. 11A-11F.

Method 1000 proceeds to operation 1004, as illustrated in FIG. 10, in which an integrated memory package can be formed. For example, with reference to FIG. 3, integrated memory package 320 may be formed.

Method 1000 proceeds to operation 1006, as illustrated in FIG. 10, in which the integrated memory package can be stacked on the interposer structure to form a stacked package structure using hybrid bonding. For example, with reference to FIG. 3, integrated memory package 320 can be stacked on and coupled to interposer structure 310 to form a stacked package structure using hybrid bonding.

Method 1000 proceeds to operation 1008, as illustrated in FIG. 10, in which the stacked package structure can be disposed on a PCB. For example, with reference to FIG. 3, the stacked package structure formed by interposer structure 310 and integrated memory device 320 can be disposed on PCB 130 and connected to PCB 130 through solder balls.

FIG. 11A is a flowchart of a method 1100 for forming an interposer structure, according to some aspects of the present disclosure. FIGS. 11B-11F illustrate a fabrication process for forming an interposer structure, according to some aspects of the present disclosure. An example of the interposer structure described in FIGS. 11A-11F can be interposer structure 310 of FIG. 3. FIGS. 11A-11F will be described together. It is understood that the operations shown in method 1100 are not exhaustive and that other operations can be performed as well before, after, or between any of the illustrated operations. Further, some of the operations may be performed simultaneously, or in a different order than shown in FIG. 11A.

Referring to FIG. 11A, method 1100 starts at operation 1102, in which a device circuit can be formed. Method 1100 may proceed to operation 1104, as illustrated in FIG. 11A, in which a first interconnect bridge can be formed. Method 1100 may proceed to operation 1106, as illustrated in FIG. 11A, in which the device circuit can be disposed on the first interconnect bridge. For example, device circuit 106 such as an SoC can be formed. With reference to FIG. 11B, first interconnect bridge 302 may be formed. With reference to FIG. 11C, device circuit 106 can be disposed on first interconnect bridge 302. Device circuit 106 may be electrically connected to first interconnect bridge 302.

Method 1100 may proceed to operation 1108, as illustrated in FIG. 11A, in which a set of vertical conductive elements surrounding the device circuit can be formed on the first interconnect bridge. For example, with reference to FIG. 11D, a set of conductive structures can be disposed vertically on first interconnect bridge 302 and electrically bonded to a set of contacts on first interconnect bridge 302 to form a set of vertical conductive elements 202, respectively.

Method 1100 may proceed to operation 1110, as illustrated in FIG. 11A, in which the device circuit and the set of vertical conductive elements can be encapsulated using a molding layer. For example, as illustrated in FIG. 11E, molding layer 110 can be formed to encapsulate device circuit 106 and the set of vertical conductive elements 202.

Method 1100 may proceed to operation 1112, as illustrated in FIG. 11A, in which a second interconnect bridge can be formed on the molding layer. For example, as illustrated in FIG. 11F, second interconnect bridge 304 can be formed on molding layer 110. The set of vertical conductive elements 202 can be electrically bonded to a set of contacts on second interconnect bridge 304, respectively.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A semiconductor packaging structure, comprising:
a device package, comprising:
a substrate;
a device circuit disposed on and coupled to the substrate;
a set of vertical conductive elements disposed on and coupled to the substrate, wherein the set of vertical conductive elements is disposed on a periphery of the device circuit; and
a molding layer encapsulating the device circuit and the set of vertical conductive elements; and
a first memory package stacked on the molding layer, and coupled to the substrate through the set of vertical conductive elements.

2. The semiconductor packaging structure of claim 1, further comprising:
a second memory package disposed on and coupled to the substrate side by side with the device package.

3. The semiconductor packaging structure of claim 1, wherein:
the device circuit is disposed on a first side of the substrate; and
the semiconductor packaging structure further comprises:
a printed circuit board (PCB) disposed on a second side opposite to the first side of the substrate, and coupled to the substrate on the second side of the substrate.

4. The semiconductor packaging structure of claim 3, further comprising:
a second memory package disposed on the PCB side by side with the device package and coupled to the PCB.

5. The semiconductor packaging structure of claim 4, wherein:
the device circuit comprises a system on chip (SoC), and the device package comprises an SoC package;
the first memory package comprises a volatile memory device; and
the second memory package comprises a non-volatile memory device and a memory controller.

6. The semiconductor packaging structure of claim 3, wherein:
the device circuit comprises a system on chip (SoC), and the device package comprises an SoC package; and
the first memory package is an integrated memory package comprising a volatile memory device, a non-volatile memory device, and a memory controller.

7. The semiconductor packaging structure of claim 1, wherein the set of vertical conductive elements comprises one or more conductive elements that are vertically bonded to one or more contacts on the substrate, respectively.

8. The semiconductor packaging structure of claim 1, wherein a material of the set of vertical conductive elements comprises gold.

9. The semiconductor packaging structure of claim 1, wherein a size of a top surface of a vertical conductive element from the set of vertical conductive elements is equal to a size of a bottom surface of the vertical conductive element.

10. A semiconductor packaging structure, comprising:
an interposer structure, comprising:
a first interconnect bridge, comprising:
a stack of conductive layers and dielectric layers that are disposed alternately; and
an interconnect structure formed in the stack and penetrating at least part of the stack to connect to a conductive layer in the stack;
a device circuit disposed on the first interconnect bridge, and coupled to the first interconnect bridge;
a set of conductive elements disposed on the first interconnect bridge and coupled to the first interconnect bridge, wherein the set of conductive elements is disposed on a periphery of the device circuit, and the interconnect structure of the first interconnect bridge is connected to at least one conductive element from the set of conductive elements; and
a molding layer encapsulating the device circuit and the set of conductive elements.

11. The semiconductor packaging structure of claim 10, wherein:
the device circuit is coupled to the interconnect structure through a set of solder balls formed on the first interconnect bridge; or
the device circuit is coupled to the interconnect structure using hybrid bonding.

12. The semiconductor packaging structure of claim 10, wherein the set of conductive elements is vertically bonded to a first set of contacts on the first interconnect bridge, respectively.

13. The semiconductor packaging structure of claim 10, wherein:
the device circuit and the set of conductive elements are formed on a first side of the first interconnect bridge; and
the semiconductor packaging structure further comprises a printed circuit board formed on a second side opposite to the first side of the first interconnect bridge and coupled to the first interconnect structure of the first interconnect bridge.

14. The semiconductor packaging structure of claim 10, wherein:
the interposer structure further comprises a second interconnect bridge disposed on the molding layer and coupled to the set of conductive elements; and
the semiconductor packaging structure further comprises an integrated memory package stacked on and coupled to the second interconnect bridge of the interposer structure.

15. The semiconductor packaging structure of claim 14, wherein the integrated memory package is coupled to the second interconnect bridge using hybrid bonding.

16. The semiconductor packaging structure of claim 14, wherein the set of conductive elements is vertically bonded to a second set of contacts on the second interconnect bridge, respectively.

17. The semiconductor packaging structure of claim 14, wherein:
the device circuit comprises a system on chip (SoC); and
the integrated memory package comprises a volatile memory device, a non-volatile memory device stacked on the volatile memory device, and a memory controller.

18. An interposer structure, comprising:
a first interconnect bridge;
a device circuit disposed on the first interconnect bridge, and coupled to the first interconnect bridge;
a set of conductive elements disposed on the first interconnect bridge and coupled to the first interconnect bridge, wherein the set of conductive elements is disposed on a periphery of the device circuit;
a molding layer encapsulating the device circuit and the set of conductive elements; and
a second interconnect bridge disposed on the molding layer, and coupled to the set of conductive elements.

19. The interposer structure of claim 18, wherein:
the first interconnect bridge comprises:
a first stack of conductive layers and dielectric layers that are disposed alternately; and
a first interconnect structure formed in the first stack and penetrating at least part of the first stack to connect to a first conductive layer in the first stack; and
the second interconnect bridge comprises:
a second stack of conductive layers and dielectric layers that are disposed alternately; and
a second interconnect structure formed in the second stack and penetrating at least part of the second stack to connect to a second conductive layer in the second stack.

20. The interposer structure of claim 19, wherein at least one conductive element from the set of conductive elements is connected to the first interconnect structure of the first interconnect bridge and the second interconnect structure of the second interconnect bridge.
